(19) United States
(12) Patent Application Publication
(10) Pub. No.: US 2025/0318120 A1
(43) Pub. Date: Oct. 9, 2025

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventors: Da Yung BYUN, Gyeonggi-do (KR); Yoo Hyun NOH, Gyeonggi-do (KR)

(21) Appl. No.: 18/764,152

(22) Filed: Jul. 4, 2024

(30) Foreign Application Priority Data
Apr. 9, 2024 (KR) 10-2024-0047770

(51) Int. Cl. H10B 43/27; H01L 23/00; H01L 25/065; H01L 25/18; H10B 41/27; H10B 41/41; H10B 43/40; H10B 80/00

(52) U.S. Cl. CPC H10B 43/27; H01L 24/08; H01L 25/0657; H01L 25/18; H10B 41/27; H10B 41/41; H10B 43/40; H10B 80/00; H01L 2224/08145; H01L 2924/1431; H01L 2924/14511

(57) ABSTRACT

A semiconductor device may include a stack including insulating layers and sacrificial layers alternately stacked, an interlayer insulating layer disposed on the stack, an insulating plug passing through the stack and the interlayer insulating layer, and a contact plug including a first portion extending between the stack and the insulating plug and having a first central axis, and a second portion extending between the interlayer insulating layer and the insulating plug and having a second central axis dislocated from the first central axis.

### CROSS-REFERENCE TO RELATED APPLICATION

This application claims priority under 35 U.S.C. § 119 to Korean Patent Application No. 10-2024-0047770 filed on Apr. 9, 2024, which is incorporated herein by reference in its entirety.

### BACKGROUND

### 1. Technical Field

Embodiments of the present disclosure relate generally to an electronic device and a method of manufacturing the electronic device, and more particularly, to a semiconductor device and a method of manufacturing the semiconductor device.

### 2. Related Art

An integration degree of a semiconductor device is mainly determined by the area occupied by a unit memory cell. Recently, as improvements in the integration degree of two-dimensional semiconductor devices in which memory cells are formed in a single layer on a substrate reaches a limit, three-dimensional semiconductor devices in which memory cells are stacked in multiple layers over a substrate have been proposed. In addition, various structures and manufacturing methods are being developed in order to improve the operational and structural reliability of the three-dimensional semiconductor devices.

### SUMMARY

According to an embodiment of the present disclosure, a three-dimensional semiconductor device (hereinafter referred to simply as a semiconductor device) may include a stack including insulating layers and sacrificial layers alternately stacked, an interlayer insulating layer disposed on the stack, an insulating plug passing through the stack and the interlayer insulating layer, and a contact plug including a first portion extending between the stack and the insulating plug and having a first central axis, and a second portion extending between the interlayer insulating layer and the insulating plug and having a second central axis dislocated from the first central axis.

According to an embodiment of the present disclosure, a semiconductor device may include a peripheral circuit, a source structure disposed on or over the peripheral circuit, a contact pad passing through the source structure, a stack disposed on or over the source structure and including insulating layers and sacrificial layers alternately stacked, an interlayer insulating layer disposed on the stack, an insulating plug passing through the stack and the interlayer insulating layer and connected to the contact pad, and a contact plug passing through the insulating plug and connected to the contact pad, and including a first portion having a first central axis, and a second portion disposed on the first portion and having a second central axis dislocated from the first central axis.

According to an embodiment of the present disclosure, a method of manufacturing a semiconductor device may include forming a stack including first material layers and second material layers alternately stacked, forming a first opening passing through the stack, forming an insulating plug in the first opening, forming a second opening passing through the insulating plug and exposing an uppermost second material layer among the second material layers, expanding the second opening along the insulating plug, and forming a contact plug in the second opening.

### BRIEF DESCRIPTION OF THE DRAWINGS

FIGS. 1A to 1D are diagrams illustrating a semiconductor device according to an embodiment of the present disclosure.

FIG. 2 is a diagram illustrating a semiconductor device according to an embodiment of the present disclosure.

FIG. 3 is a diagram illustrating a semiconductor device according to an embodiment of the present disclosure.

FIGS. 4A to 4D are diagrams illustrating a method of manufacturing a semiconductor device according to an embodiment of the present disclosure.

FIGS. 5A to 5E are diagrams illustrating a method of manufacturing a semiconductor device according to an embodiment of the present disclosure.

### DETAILED DESCRIPTION

An embodiment of the present disclosure provides a semiconductor device and a method of manufacturing the semiconductor device having a stable structure and an improved characteristic.

According to the present technology, a semiconductor device having a stable structure and improved reliability may be provided.

Hereinafter, embodiments according to the technical concepts of the present disclosure are described with reference to the accompanying drawings.

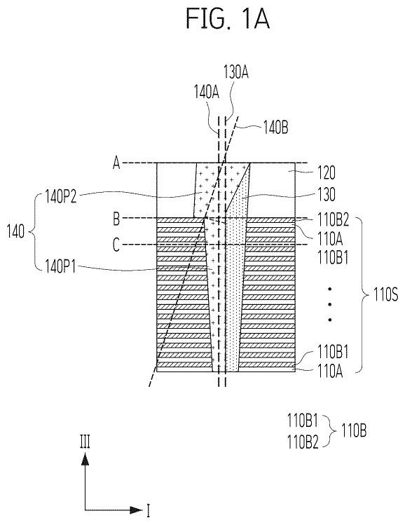

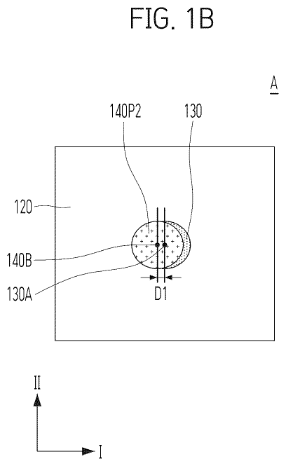

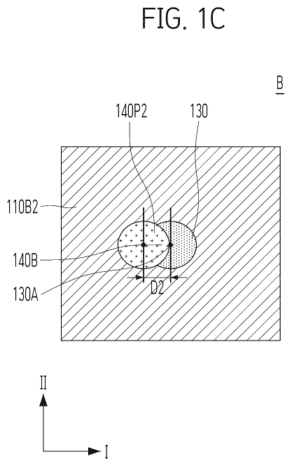

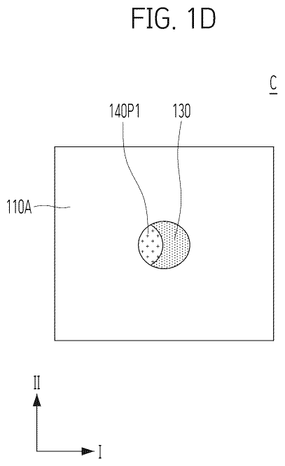

FIGS. 1A to 1D are diagrams illustrating a semiconductor device according to an embodiment of the present disclosure. FIG. 1A is a cross-sectional view, FIG. 1B is a plan view A of FIG. 1A, FIG. 1C is a plan view B of FIG. 1A, and FIG. 1D is a plan view C of FIG. 1A.

Referring to FIGS. 1A to 1D, the semiconductor device may include a stack 110S, an interlayer insulating layer 120, an insulating plug 130, and a contact plug 140.

The stack 110S may include insulating layers 110A and sacrificial layers 110B (110B1 and 110B2) alternately stacked. Each of the sacrificial layers 110B1 is positioned between two adjacent insulating layers 110A while the uppermost sacrificial layer 110B2 is in contact with the interlayer insulating layer 120 on a top surface thereof. The sacrificial layers 110B may include a material having a selectivity with respect to the insulating layers 110A. For example, the insulating layers 110A may include an insulating material such as, for example, an oxide, and the sacrificial layers 110B may include an insulating material such as nitride.

The interlayer insulating layer 120 may be disposed on the stack 110S. The interlayer insulating layer 120 may include a material substantially the same as or different from that of the insulating layers 110A of the stack 110S. For example, the interlayer insulating layer 120 may include an insulating material such as, for example, an oxide.

The insulating plug 130 may extend through the stack 110S and the interlayer insulating layer 120. The insulating plug 130 may have a third central axis 130A for example, as illustrated, passing through a center of the insulating plug 130 and extending in a direction parallel to the stacking direction of the stack 110S. For example, in the illustrated embodiment, the third central axis 130A may extend in a vertical direction. In a process of forming the contact plug 140, the insulating plug 130 may be used for aligning the contact plug 140 so that the contact plug 140 extends in the direction parallel to the stacking direction of the stack 110S. For example, the insulating plug 130 may be used to align the contact plug 140 so that the contact plug 140 extends along the third central axis 130A. The insulating plug 130 may include a material substantially the same as or different from that of the insulating layers 110A. For example, the insulating plug 130 may include an insulating material such as an oxide.

The contact plug 140 may pass through the insulating plug 130 at a position biased from the third central axis 130A of the insulating plug 130. For example, the contact plug 140 may pass through the insulating plug 130 in a state in which the contact plug 140 is biased in one direction from the third central axis 130A of the insulating plug 130. The contact plug 140 may include a conductive material such as, for example, tungsten.

The contact plug 140 may extend through the insulating plug 130, the stack 110S, and the interlayer insulating layer 120. The contact plug 140 may include a first portion 140P1 and a second portion 140P2 disposed on the first portion 140P1. Referring to FIG. 1A, the first portion 140P1 may extend between the insulating plug 130 and the stack 110S. Therefore, a partial sidewall of the first portion 140P1 may contact the insulating plug 130, and a remaining sidewall of the first portion 140P1 may contact the stack 110S. The second portion 140P2 may extend between the insulating plug 130 and the interlayer insulating layer 120. Therefore, a partial sidewall of the second portion 140P2 may contact the insulating plug 130, and a remaining sidewall of the second portion 140P2 may contact the interlayer insulating layer 120. The second portion 140P2 may be wider than the first portion 140P1 and may extend laterally over and in direct contact with a top surface of the uppermost sacrificial layer 110B2 among the sacrificial layers 110B of the stack 110S.

The first portion 140P1 may have a first central axis 140A. The second portion 140P2 may have a second central axis 140B dislocated from the first central axis 140A by a small lateral distance. The first central axis 140A and the second central axis 140B may not be parallel and may cross with each other. In the illustrated embodiment of FIG. 1A, for example, as illustrated, the first central axis 140A extends in a direction parallel to the third central axis 130A, and the second central axis 140B extends in a direction crossing the third central axis 130A. The first central axis 140A refers to an axis passing through a center of the first portion 140P1, and the second central axis 140B refers to an axis passing through a center of the second portion 140P2.

The second central axis 140B of the second portion 140P2 may extend in a direction tilted from a vertical direction as shown in FIG. 1A. In this case, because the first portion 140P1 extends along the second central axis 140B, the first portion 140P1 may deviate from a target direction. For example, as illustrated, the target direction of the first portion 140P1 of the contact plug 140 may be a vertical direction. According to an embodiment of the present disclosure, the third central axis 130A of the insulating plug 130 may also extend in the vertical direction. The first portion 140P1 may extend along the third central axis 130A of the insulating plug 130, and the first portion 140P1 may be landed at a target position. According to an embodiment of the present disclosure, a landing margin of the first portion 140P1 may be secured, and the contact plug 140 may be landed at the target position.

As an example, this specification describes an embodiment in which the second central axis 140B of the second portion 140P2 extends in a direction tilted from the vertical direction, but the second central axis 140B may extend in a direction parallel to the vertical direction. For example, the second central axis 140B of the second portion 140P2 may extend in a direction parallel to the third central axis 130A of the insulating plug 130. Referring to FIGS. 1B to 1D, the first portion 140P1 and the second portion 140P2 of the contact plug 140 may have different plane shapes. The insulating plug 130 may surround the contact plug 140 in different shapes according to a level at which the insulating plug 130 is located.

At an A level (see FIG. 1B), the second portion 140P2 of the contact plug 140 may have a normal shape such as a circle, an oval, or a quadrangle. The insulating plug 130 may have a shape surrounding a partial sidewall of the second portion 140P2. For example, at the A level, the second portion 140P2 and the insulating plug 130 may have a circular shape. For example, as illustrated, two circular shapes may partially overlap with each other. The second portion 140P2 may have a normal shape of a circular shape by including an overlapping portion, and the insulating plug 130 may have a non-normal shape as a remaining portion except for the overlapping portion. In this case, the second portion 140P2 may have a circular shape, and the insulating plug 130 may have a crescent shape. For example, as illustrated, the second central axis 140B of the second portion 140P2 and the third central axis 130A of the insulating plug 130 may be spaced apart by a first distance D1.

At a B level (see FIG. 1C), the second portion 140P2 may have a normal shape, and the insulating plug 130 may have a shape surrounding a partial sidewall of the second portion 140P2. The second portion 140P2 may protrude from a sidewall of the insulating plug 130. For example, as illustrated, the insulating plug 130 may have a crescent shape. Compared to the A level, the two circular shapes may overlap less at the B level. In addition, compared to the A level, the second central axis 140B and the third central axis 130A may be spaced apart by a second distance D2 greater than the first distance D1 at the B level. In this case, the insulating plug 130 may surround less sidewall of the second portion 140P2.

At a C level (FIG. 1D), the first portion 140P1 may correspond to a portion where the second portion 140P2 and the insulating plug 130 overlap at the B level. The first portion 140P1 may correspond to a portion of the normal shape of the second portion 140P2. The insulating plug 130 may surround a partial sidewall of the first portion 140P1. In this case, the first portion 140P1 and the insulating plug 130 may be combined to have one normal shape.

In the embodiment of FIG. 1D, the contact plug 140 protrudes from the insulating plug 130 in a first direction I, but the embodiments are not limited thereto, and the contact plug 140 may protrude from the insulating plug 130 in a second direction II or between the first direction I and the second direction II.

According to the above described structure, the contact plug 140 may include the first portion 140P1 having the first central axis 140A and the second portion 140P2 having the second central axis 140B dislocated from the first central axis 140A. The insulating plug 130 may have the third central axis 130A. The first central axis 140A and the third central axis 130A may extend in a parallel direction, and the second central axis 140B may extend in a direction crossing the first central axis 140A and the third central axis 130A.

Even though the second central axis 140B of the second portion 140P2 is tilted, the first portion 140P1 of the contact plug 140 may extend along the third central axis 130A of the insulating plug 130, and thus the first portion 140P1 may be landed at the target position. That is, the contact plug 140 may be landed at the target position.

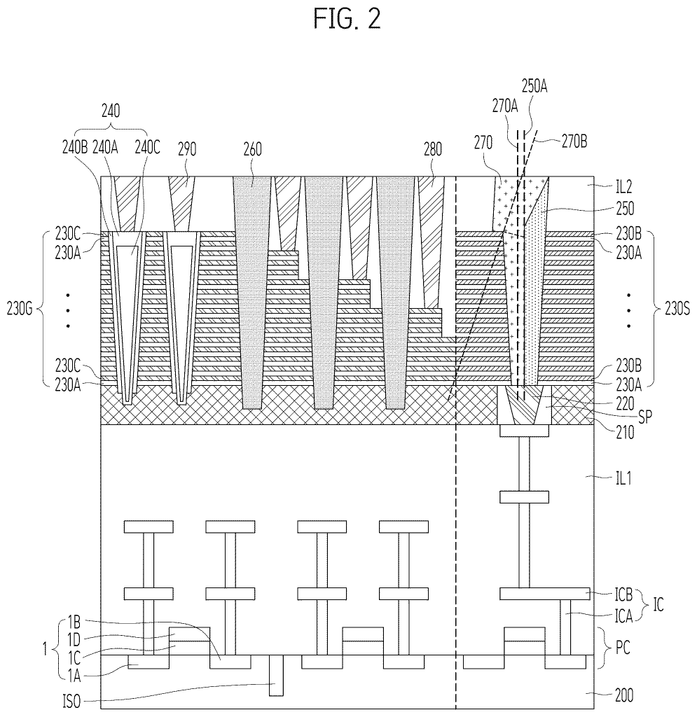

FIG. 2 is a diagram illustrating a semiconductor device according to an embodiment of the present disclosure. Hereinafter, a content overlapping the content described above may be omitted.

Referring to FIG. 2, the semiconductor device may include a substrate 200, a peripheral circuit PC, a source structure 210, a contact pad 220, a stack 230S, a gate structure 230G, channel structures 240, supports 260, an insulating plug 250, and a contact plug 270. The semiconductor device may further include first contact vias 280, second contact vias 290, an isolation layer ISO, an interconnection structure IC, a first interlayer insulating layer IL1, a second interlayer insulating layer IL2, and an insulating spacer SP.

The peripheral circuit PC may be disposed on or over the substrate 200. The peripheral circuit PC may include a transistor 1. The transistor 1 may include junctions 1A and 1B, a gate electrode 1D, and a gate insulating layer 1C. For example, as illustrated, the gate insulating layer 1C may be disposed between the gate electrode 1D and the substrate 100. The isolation layer ISO may be disposed in the substrate 200, and an active region of the transistor 1 may be defined by the isolation layer ISO.

The interconnection structure IC may be disposed on or over the peripheral circuit PC. The first interconnection structure IC may be disposed in the first interlayer insulating layer IL1. For example, as illustrated, the first interlayer insulating layer IL1 may be disposed on the substrate 200. The interconnection structure IC may include vias ICA extending in the stacking direction and lines ICB extending parallel to the top surface of the substrate 200. The interconnection structure IC may be connected to the peripheral circuit PC. For example, at least one of the vias ICA may be connected to the transistor 1. At least one of the vias ICA may connect the lines ICB with each other. The lines ICB may connect the vias ICA with each other. The interconnection structure IC may include a conductive material such as, for example, tungsten. The first interlayer insulating layer IL1 may include an insulating material such as, for example, an oxide or nitride.

The contact pad 220 may pass through the source structure 210. For example, as illustrated, the source structure 210 may be disposed on or over the peripheral circuit PC. The insulating spacer SP may surround a sidewall of the contact pad 220. The insulating spacer SP may prevent the source structure 210 and the contact pad 220 from being electrically connected. The contact pad 220 may be electrically connected to the peripheral circuit PC. For example, the contact pad 220 may be electrically connected to the peripheral circuit PC through the interconnection structure IC. The contact pad 220 may be a discharge contact pad for discharging a charge accumulated in the source structure 210 in a manufacturing process of the semiconductor device. The contact pad 220 may include a conductive material such as, for example, tungsten. The source structure 210 may include a conductive material such as, for example, polysilicon or metal. The insulating spacer SP may include an insulating material such as, for example, an oxide.

The stack 230S may be disposed on or over the source structure 210. The stack 230S may include insulating layers 230A and sacrificial layers 230B alternately stacked. The gate structure 230G may be disposed at a same level as the level of the stack 230S. The gate structure 230G may include insulating layers 230A and conductive layers 230C alternately stacked over the source structure 210. For example, as illustrated, the conductive layers 230C may be formed by replacing the sacrificial layers 230B in a process of manufacturing the semiconductor device. The gate structure 230G may include a step structure. The gate structure 230G may include a step structure in which a top surface of the conductive layers 230C is exposed. For example, as illustrated, the insulating layers 230A may include an insulating material such as, for example, an oxide, the sacrificial layers 230B may include a sacrificial material such as nitride, and the conductive layers 230C may include a conductive material such as, for example, tungsten, molybdenum, or polysilicon.

The insulating plug 250 may extend through the stack 230S. For example, the insulating plug 250 may extend through the stack 230S and the second interlayer insulating layer IL2 and may be connected to the contact pad 220. For example, as illustrated, the second interlayer insulating layer IL2 may be disposed on the stack 230S. The insulating plug 250 may be connected to a portion of a top surface of the contact pad 220. The insulating plug 250 may have a third central axis 250A. The third central axis 250A may extend in a direction parallel to a direction in which the stack 230S is stacked. The insulating plug 250 may include an insulating material such as, for example, an oxide. The second interlayer insulating layer IL2 may include an insulating material such as, for example, an oxide.

The contact plug 270 may extend through the insulating plug 250. For example, the contact plug 270 may extend through the insulating plug 250, the stack 230S, and the second interlayer insulating layer IL2, and may be connected to the contact pad 220. The contact plug 270 may include a first portion 270P1 and a second portion 270P2 disposed on the first portion 270P1. For example, as illustrated, the first portion 270P1 may be connected to a portion of a top surface of the contact pad 220. The first portion 270P1 and the insulating plug 250 may be connected to the top surface of the contact pad 220. A partial sidewall of the first portion 270P1 may contact the insulating plug 250, and a remaining sidewall of the first portion 270P1 may contact the stack 230S. A partial sidewall of the second portion 270P2 may contact the insulating plug 250, and a remaining sidewall of the second portion 270P2 may contact the second interlayer insulating layer IL2. The second portion 270P2 may contact a top surface of the uppermost sacrificial layer 230B among the sacrificial layers 230B of the stack 230S.

The first portion 270P1 may have a first central axis 270A. The second portion 270P2 may have a second central axis 270B dislocated from the first central axis 270A. The first central axis 270A may extend in a direction parallel to the third central axis 250A, and the second central axis 270B may extend in a direction crossing the third central axis 250A.

The contact plug 270 may be electrically connected to the peripheral circuit PC. For example, the contact plug 270 may be electrically connected to the peripheral circuit PC through the contact pad 220. The contact plug 270 may include a conductive material such as, for example, tungsten.

The channel structures 240 may extend through the gate structure 230G. For example, the channel structures 240 may extend into the source structure 210 through the gate structure 230G. Each of the channel structures 240 may include at least one of a channel layer 240A, a memory layer 240B surrounding the channel layer 240A, and an insulating core 240C in the channel layer 240A. For example, as illustrated, the channel layer 240A may be connected to the source structure 210.

The supports 260 may extend through the gate structure 230G. For example, the supports 260 may extend into the source structure 210 through the gate structure 230G. The supports 260 may prevent or reduce bending of the stack 230S during a process of forming the gate structure 230G. The supports 260 may include an insulating material such as, for example, an oxide.

The first contact vias 280 may be connected to the conductive layers 230C of the gate structure 230G, respectively. For example, the first contact vias 280 may extend through the second interlayer insulating layer IL2 and may be respectively connected to the conductive layers 230C of which a top surface is exposed through the step structure of the gate structure 230G. Heights of the respective first contact vias 280 may be different. The first contact vias 280 may include a conductive material such as, for example, tungsten.

The second contact vias 290 may be connected to the channel structures 240, respectively. For example, the second contact vias 290 may extend through the second interlayer insulating layer IL2 and may be connected to the channel layer 240A of the channel structures 240. The second contact vias 290 may include a conductive material such as, for example, tungsten.

According to the structure described above, the semiconductor device may include the contact pad 220. The contact pad 220 may be disposed on or over the peripheral circuit PC, and the contact pad 220 may be electrically connected to the peripheral circuit PC. The contact plug 270 may be electrically connected to the peripheral circuit PC through the contact pad 220.

The contact plug 270 may include the first portion 270P1 having the first central axis 270A and the second portion 270P2 having the second central axis 270B dislocated from the first central axis 270A. The insulating plug 250 may have the third central axis 250A. The first central axis 270A and the third central axis 250A may extend in a parallel direction, and the second central axis 270B may extend in a direction crossing the first central axis 270A and the third central axis 250A.

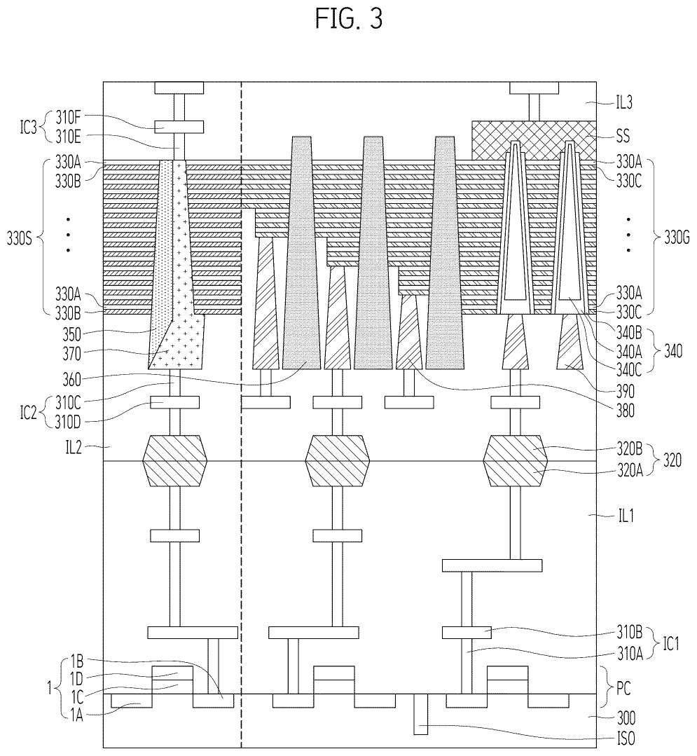

FIG. 3 is a diagram illustrating a semiconductor device according to an embodiment of the present disclosure. Hereinafter, a content overlapping the content described above may be omitted. Referring to FIG. 3, the semiconductor device may include a

substrate 300, a peripheral circuit PC, a source structure SS, a bonding structure 320, a stack 330S, a gate structure 330G, channel structures 340, an insulating plug 350, supports 360, and a contact plug 370. The semiconductor device may further include first contact vias 380, second contact vias 390, an isolation layer ISO, a first interconnection structure IC1, a second interconnection structure IC2, a third interconnection structure IC3, a first interlayer insulating layer IL1, a second interlayer insulating layer IL2, and a third interlayer insulating layer IL3. The peripheral circuit PC may be disposed on or over the substrate 300. The peripheral circuit PC may include a transistor 1. The transistor 1 may include junctions 1A and 1B, a gate electrode 1D, and a gate insulating layer 1C. The isolation layer ISO may be disposed in the substrate 200, and an active region of the transistor 1 may be defined by the isolation layer ISO.

The first interconnection structure IC1 may be disposed directly on the peripheral circuit PC however, the embodiments may not be limited in this way and one or more intermediate layers may also be used between the peripheral circuit PC and the substrate. The first interconnection structure IC1 may be disposed in the first interlayer insulating layer IL1. In the illustrated embodiment, the first interlayer insulating layer IL1 may be disposed on the substrate 300. The first interconnection structure IC1 may include first vias 310A and first lines 310B made of a conductive material such as, for example, tungsten. The first interlayer insulating layer IL1 may include an insulating material such as, for example, an oxide or nitride.

The bonding structure 320 may be disposed on or over the peripheral circuit PC. For example, the bonding structure 320 may be disposed on the first interconnection structure IC1. The bonding structure 320 may include first bonding pads 320A and second bonding pads 320B. The first bonding pads 320A may be disposed in the first interlayer insulating layer IL1. The second bonding pads 320A may be disposed on the first bonding pads 320A and inside the second interlayer insulating layer IL2. For example, as illustrated, the second interlayer insulating layer IL2 may be disposed on the first interlayer insulating layer IL1. The bonding structure 320 may include a conductive material such as, for example, copper, however, the embodiment is not limited to copper and other conductive materials may also be used. The second interlayer insulating layer IL2 may include an insulating material such as, for example, an oxide.

The second interconnection structure IC2 may be disposed on or over the bonding structure 320 and inside the second interlayer insulating layer IL2. The second interconnection structure IC2 may include second vias 310C and second lines 310D. The second interconnection structure IC2 may be connected to the bonding structure 320. For example, at least one of the second vias 310C may be connected to the second bonding pad 320B. The second interconnection structure IC2 may include a conductive material such as, for example, tungsten.

The stack 330S may be disposed over the bonding structure 320. For example, the stack 330S may be disposed over the second interlayer layer IL2 over at least one of the interconnection structures IC2. The stack 330S may include insulating layers 330A and sacrificial layers 330B alternately stacked. The gate structure 330G may be disposed at a level corresponding to the stack 330S. The gate structure 330G may include insulating layers 330A and conductive layers 330C alternately stacked. The gate structure 330G may include an inverted step structure in which a bottom surface of the conductive layers 330C is exposed.

For example, the gate structure 330G may include a step structure in which a top surface of the conductive layers 330C is exposed. In this drawing, the gate structure 330G may be shown in a rotated state. This drawing may include the gate structure 330G including an inverted step structure.

The insulating plug 350 may extend through the stack 330S and an upper portion of the second interlayer insulating layer IL2. The contact plug 370 may extend through the insulating plug 350. The contact plug 370 may be electrically connected to the peripheral circuit PC through the bonding structure 320. For example, the contact plug 370 may be connected to the bonding structure 320 through the second interconnection structure IC2 and may be electrically connected to the peripheral circuit PC through the bonding structure 320.

The channel structures 340 may extend into the source structure SS through the gate structure 330G. For example, as illustrated, the source structure SS may be disposed on or over the gate structure 330G. Each of the channel structures 340 may include at least one of a channel layer 340A, a memory layer 340B surrounding the channel layer 340A, and an insulating core 340C in the channel layer 340A. For example, as illustrated, the channel layer 340A may be connected to the source structure SS.

The supports 360 may extend into the third interlayer insulating layer IL3 through the gate structure 330G. For example, as illustrated, the third interlayer insulating layer IL3 may be disposed on the gate structure 330G and/or the stack 330S. The supports 360 may include an insulating material such as, for example, an oxide. The third interlayer insulating layer IL3 may include an insulating material such as, for example, an oxide.

The first contact vias 380 may be connected to the conductive layers 330C of the gate structure 330G, respectively. For example, the first contact vias 380 may extend through the second interlayer insulating layer IL2 and may be respectively connected to the conductive layers 330C of which a bottom surface is exposed through the inverted step structure of the gate structure 330G. The first contact vias 380 may include a conductive material such as, for example, tungsten.

The second contact vias 390 may be connected to the channel structures 340, respectively. For example, the second contact vias 390 may extend through the second interlayer insulating layer IL2 and may be connected to the channel layer 340A of the channel structures 340. The second contact vias 390 may include a conductive material such as, for example, tungsten.

The third interconnection structure IC3 may be disposed in the third interlayer insulating layer IL3. The third interconnection structure IC3 may include third vias 310E and third lines 310F. At least one of the third vias 310E may be connected to the contact plug 370. At least one of the third vias 310E may be connected to the source structure SS. At least one of the third lines 310F may be connected to the third contact via 310E. The third interconnection structure IC3 may include a conductive material such as, for example, tungsten.

According to the structure described above, the semiconductor device may include the bonding structure 320 which is disposed on or over the peripheral circuit PC and is electrically connected to the peripheral circuit PC. This structure allows the contact plug 370 to be electrically connected to the peripheral circuit PC through the bonding structure 320.

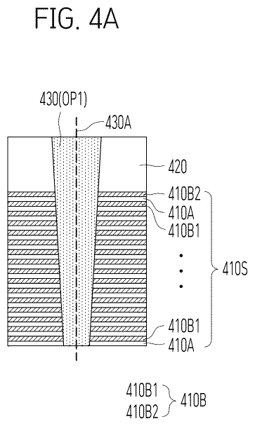

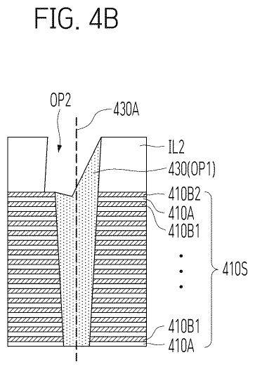

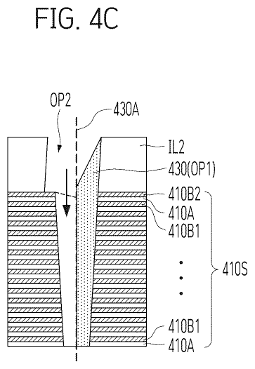

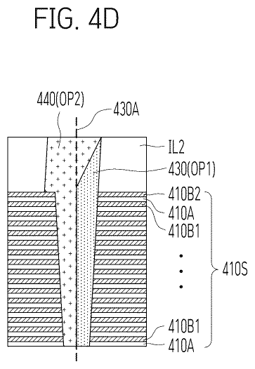

FIGS. 4A to 4D are diagrams illustrating a method of manufacturing a semiconductor device according to an embodiment of the present disclosure. Hereinafter, a content overlapping the content described above may be omitted.

Referring to FIG. 4A, first material layers 410A and second material layers 410B may be alternately stacked to form a stack 410S. The second material layers 410B may include an uppermost material layer 410B2 and remaining second material layers 410B1. The second material layers 410B may include a material having a selectivity with respect to the first material layers 410A. For example, the first material layers 410A may include an insulating material such as, for example, an oxide, and the second material layers 410B may include a sacrificial material such as nitride.

Subsequently, an interlayer insulating layer 420 may be formed on the stack 410S. For example, the interlayer insulating layer 420 may be formed on the uppermost second material layer 410B2 of the stack 410S. For example, as illustrated, the interlayer insulating layer 420 may include a material substantially the same as or different from that of the first material layers 410A. For example, the interlayer insulating layer 420 may include an insulating material such as, for example, an oxide.

Subsequently, a first opening OP1 extending through the stack 410S may be formed. For example, the first opening OP1 passing through the interlayer insulating layer 420 and the stack 410S may be formed. Subsequently, an insulating plug 430 may be formed in the first opening OP1. A central axis 430A of the insulating plug 430 may extend in a direction parallel to a direction in which the stack 410S is stacked. For example, the central axis 430A of the insulating plug 430 may extend in a vertical direction. The insulating plug 430 may include a material substantially the same as or different from that of the first material layers 410A. For example, the insulating plug 430 may include an insulating material such as, for example, an oxide.

Referring to FIG. 4B, a second opening OP2 extending through the insulating plug 430 may be formed. The second opening OP2 may be formed by etching the insulating plug 430 in a direction dislocated from the central axis 430A of the insulating plug 430. The second opening OP2 may be tilted from the central axis 430A of the insulating plug 430 to be formed. In this case, the second opening OP2 may extend through the insulating plug 430 to expose a portion of the uppermost second material layer 410B2 that is adjacent to the insulating plug 430. The uppermost second material layer 410B2 may be used as an etch stop layer. This is because the uppermost second material layer 410B2 includes a material having a selectivity with respect to the first material layers 410A, the interlayer insulating layer 420, and the insulating plug 430.

Referring to FIG. 4C, the second opening OP2 may be expanded along the insulating plug 430. For example, the second opening OP2 may be expanded along the central axis 430A of the insulating plug 430. Because the central axis 430A of the insulating plug 430 may extend in the vertical direction, the second opening OP2 may expand in the vertical direction. While expanding the second opening OP2, the uppermost second material layer 410B2 may be used as an etch barrier.

An extension direction of the second opening OP2 may be corrected through the insulating plug 430. For example, when the second opening OP2 vertically passing through the stack 410S is to be formed, the second opening OP2 may be tilted and formed due to a limitation of a process. In this case, the second opening OP2 may extend along a central axis of the tilted second opening OP2, and a lower portion of the second opening OP2 may deviate from a target position. According to an embodiment of the present disclosure, because the second opening OP2 may be expanded along a central axis 430A of the insulating plug 430, the second opening OP2 may be expanded in a direction parallel to the central axis 430A of the insulating plug 430. The extension direction of the tilted second opening OP2 may be aligned in the vertical direction, and the second opening OP2 may be landed at the target position.

For reference, the second opening OP2 may be formed in a misaligned state in which an overlay of the insulating plug 430 is greatly distorted. In this case, the second opening OP2 may be formed in a direction parallel to the central axis 430A of the insulating plug 430. However, according to an embodiment of the present disclosure, the second opening OP2 may be expanded along the central axis 430A of the insulating plug 430A in order to land the second opening OP2 at the target position.

Referring to FIG. 4D, a contact plug 440 may be formed in the second opening OP2. The contact plug 440 may be formed to be tilted between the interlayer insulating layer 420 and the insulating plug 430, and may be formed in a direction parallel to the central axis 430A of the insulating plug 430 between the stack 410S and the insulating plug 430. The contact plug 440 may include a conductive material such as, for example, tungsten.

According to the manufacturing method described above, the second opening OP2 exposing the uppermost second material layer 410B2 among the second material layers 410B of the stack 410S may be formed. For example, as illustrated, the uppermost second material layer 410B2 may be used as an etch stop layer. Subsequently, the second opening OP2 may be expanded. The uppermost second material layer 410B2 may be used as an etch barrier because the uppermost second material layer 410B2 is made of a material having a selectivity with respect to the first material layers 410A, the interlayer insulating layer 420, and the insulating plug 430.

In addition, using the method of the present disclosure, the extension direction of the second opening OP2 formed through the insulating plug 430 and formed may be corrected. For example, the tilted and formed second opening OP2 may be expanded by aligning the second opening OP2 along the central axis 430A of the insulating plug 430. The second opening OP2 may be expanded in the vertical direction and the second opening OP2 may be landed at the target position.

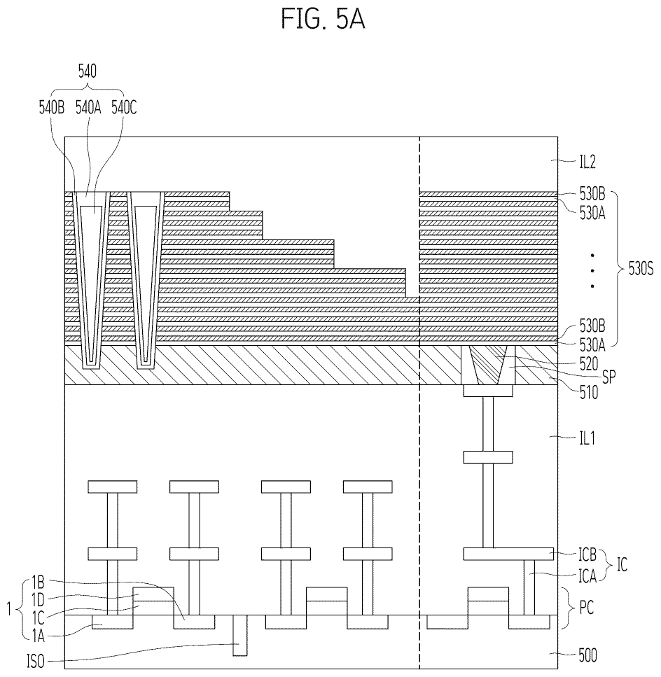

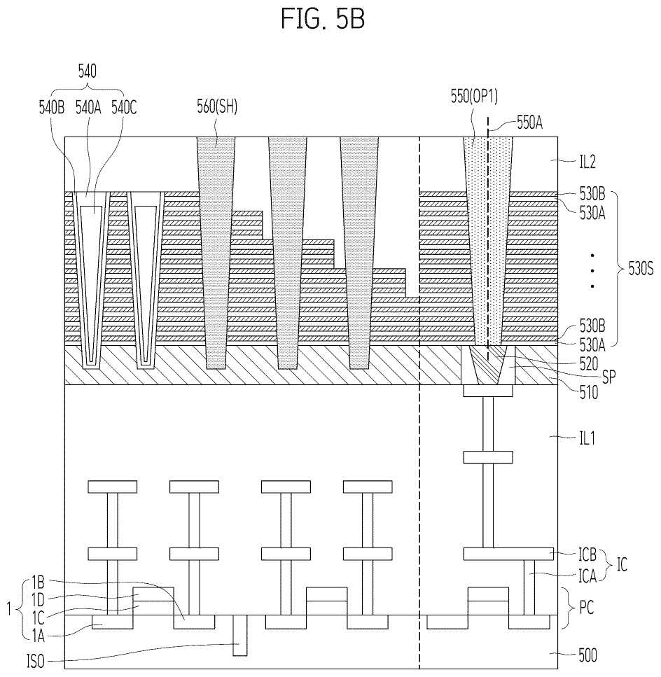

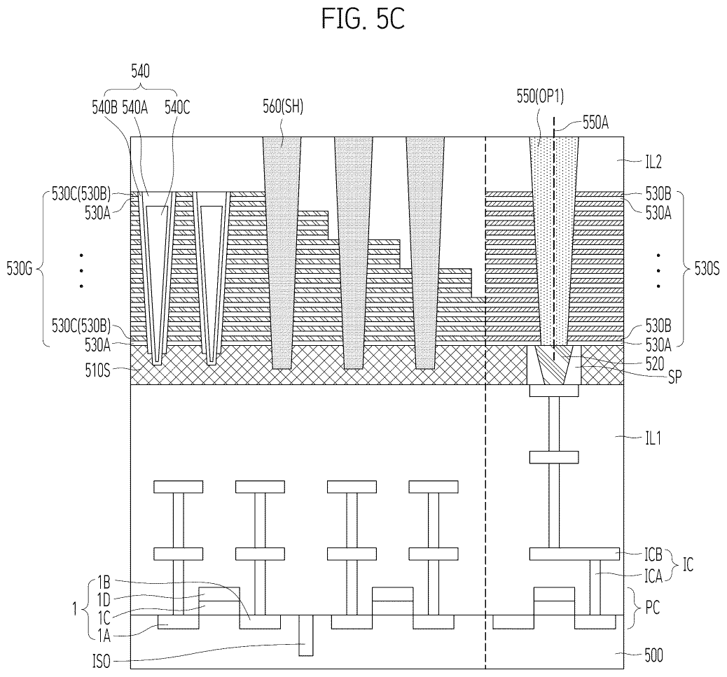

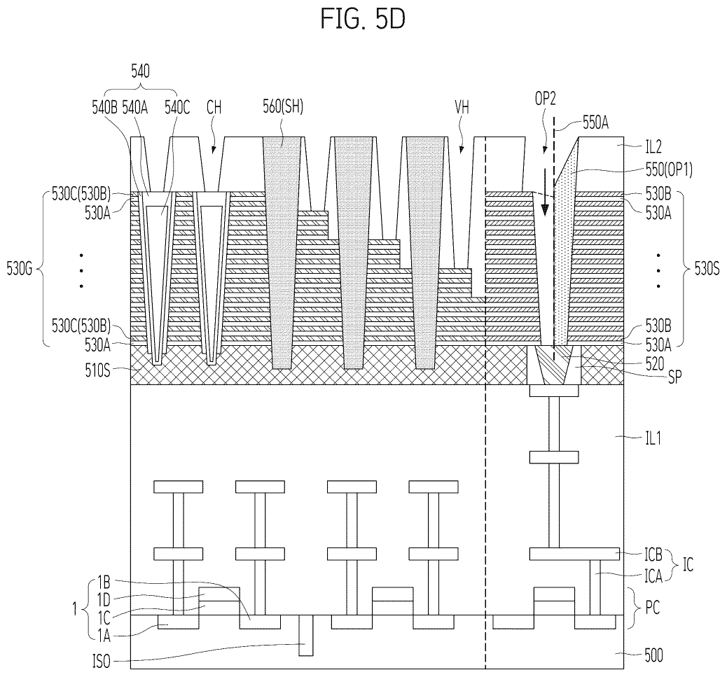

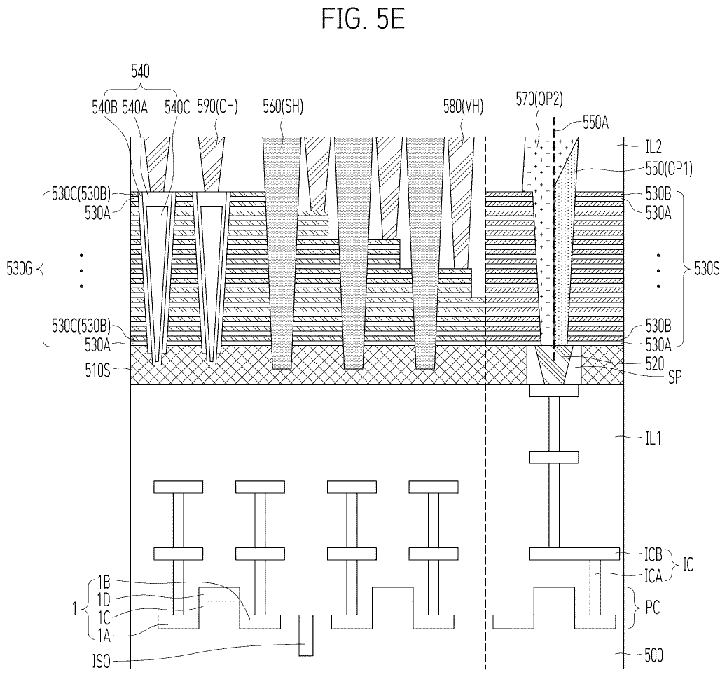

FIGS. 5A to 5E are diagrams illustrating a method of manufacturing a semiconductor device according to an embodiment of the present disclosure. Hereinafter, a content overlapping the content described above may be omitted.

Referring to FIG. 5A, a peripheral circuit PC may be formed on or over substrate 500. The peripheral circuit PC may include a transistor 1. The transistor 1 may include junctions 1A and 1B, a gate insulating layer 1C, and a gate electrode 1D. An isolation layer ISO may be formed in the substrate 500 and may define an active region of the transistor 1.

Subsequently, an interconnection structure IC may be formed on or over the peripheral circuit PC. The interconnection structure IC may be formed in a first interlayer insulating layer IL1. For example, in an embodiment, the first interlayer insulating layer IL1 may be formed on the substrate 500 and the interconnection structure IC including vias ICA and lines ICB may be formed inside the first interlayer insulating layer IL1. At least one of the vias ICA may be connected to the peripheral circuit PC. Alternatively, at least one of the vias ICA may connect the lines ICB with each other. The interconnection structure IC1 may include a conductive material such as, for example, tungsten. The first interlayer insulating layer IL1 may include an insulating material such as, for example, an oxide.

Subsequently, a source layer 510 may be formed on or over the peripheral circuit PC. Subsequently, a contact pad 520 may be formed to be connected to the interconnection structure IC by passing through the source layer 510. For example, as illustrated, the contact pad 520 may be a discharge contact pad for discharging a charge accumulated in the source structure in a subsequent process. An insulating spacer SP may surround a sidewall of the contact pad 520. The contact pad 520 may include a conductive material such as, for example, tungsten, and the insulating spacer SP may include an insulating material such as, for example, an oxide.

Subsequently, a stack 530S may be formed by alternately stacking first material layers 530A and second material layers 530B over the source layer 510. The stack 530S may include a step structure exposing a top surface of the second material layers 530B. The second material layers 530B may include a material having a selectivity with respect to the first material layers 530A. For example, the first material layers 530A may include an insulating material such as, for example, an oxide, and the second material layers 530B may include a sacrificial material such as nitride.

Channel structures 540 extending into the source layer 510 through the stack 530S may be formed. For reference, after forming the channel structures 540, the step structure of the stack 530S may also be formed. Each of the channel structures 540 may include at least one of a channel layer 540A, a memory layer 540B surrounding the channel layer 540A, and an insulating core 540C in the channel layer 540A.

Subsequently, a second interlayer insulating layer IL2 may be formed on the stack 530S. The second interlayer insulating layer IL2 may include a material substantially the same as or different from that of the first material layers 530A of the stack 530S. For example, the second interlayer insulating layer IL2 may include an insulating material such as an oxide.

Referring to FIG. 5B, an insulating plug 550 extending through the stack 530S may be formed. First, a first opening OP1 may be formed passing through the stack 530S and to expose the contact pad 520 through the stack 530S. The first opening OP1 may extend in the vertical direction. Subsequently, an insulating plug 550 may be formed in the first opening OP1 with a central axis 550A of the insulating plug 550 extending in the vertical direction. In this case, the insulating plug 550 may be connected to the contact pad 520. The insulating plug 550 may include a material substantially the same as or different from that of the first material layers 510A of the stack 510S. For example, the insulating plug 550 may include an insulating material such as, for example, an oxide.

Supports 560 extending through the stack 530S may be formed. First, support holes SH may be formed to pass through the second interlayer insulating layer IL2 and the stack 530S and extend partially into the source layer 510. For example, a plurality of the support holes SH may be formed extending into the source layer 510 through the stack 530S. When forming the first opening OP1, the support holes SH may be formed. Therefore, the support holes SH may extend in the vertical direction. Subsequently, the supports 560 may be formed by filling the support holes SH with an insulating material. When forming the insulating plug 550, the supports 560 may be formed. Therefore, the supports 560 may include an insulating material such as, for example, an oxide.

Referring to FIG. 5C, a gate structure 530G may be formed by replacing the second material layers 530B with third material layers 530C. For example, after forming openings by removing the second material layers 530B through a slit (not shown), the third material layers 530C may be formed in the openings. Accordingly, the gate structure 530G including the first material layers 530A and the third material layers 530C alternately stacked may be formed. For example, as illustrated, a portion of the second material layers 530B may not be replaced with the third material layers 530C and may remain. The third material layers 530C may include a conductive material such as, for example, tungsten, molybdenum, or polysilicon.

Subsequently, a source structure 510S may be formed. For example, after forming openings by removing a sacrificial material in the source layer 510 through a slit, the source structure 510S may be formed by forming a semiconductor material or the like in the opening. Before forming the source structure 510S, the memory layer 540B of the channel structures 540 may be removed through the slit. In this case, the channel layer 540A of the channel structures 540 may be exposed, and the channel layer 540A may be connected to the source structure 510S.

Referring to FIG. 5D, a second opening OP2 extending through the insulating plug 550 may be formed. The second opening OP2 may be tilted from the central axis 550A of the insulating plug 550 to be formed. In this case, the second opening OP2 may extend through the insulating plug 550 to expose an uppermost second material layer 530B among the second material layers 530B. For example, as illustrated, the uppermost second material layer 530B may be used as an etch stop layer. This is because the uppermost second material layer 530B may include a material having a selectivity with respect to the first material layers 530A, the second interlayer insulating layer IL2, and the insulating plug 550.

Subsequently, a second opening OP2 may be expanded along the central axis 550A of the insulating plug 550. Because the central axis 550A of the insulating plug 550 may extend in the vertical direction, the second opening OP2 may expand in the vertical direction. While expanding the second opening OP2, the uppermost second material layer 530B may be used as an etch barrier.

According to an embodiment of the present disclosure, because the second opening OP2 may be expanded along the central axis 550A of the insulating plug 550, the second opening OP2 may be expanded in a direction parallel to the central axis 550A of the insulating plug 550. Therefore, an extension direction of the tilted second opening OP2 may be aligned in the vertical direction, and the second opening OP2 may be landed at the target position.

Via holes VH respectively exposing the third material layers 530C may be formed. For example, the via holes VH may be formed to extend through the second interlayer insulating layer IL2 and respectively expose the third material layers 530C. When forming and expanding the second opening OP2, the via holes VH may be formed. For reference, in this drawing, the via hole VH exposing the uppermost third material layer 530C among three grouped third material layers 530C is shown, but via holes VH respectively exposing all of the third material layers 530C may also be formed. In addition, in this drawing, the via holes VH extending in the vertical direction are shown, but the via holes VH may be tilted like the second opening OP2 to be formed. In this case, because the via holes VH may be formed at a relatively small depth, the via holes VH may be landed at the target position.

Contact holes CH exposing the channel structures 540 may be formed. For example, the contact holes CH extending through the second interlayer insulating layer IL2 and respectively exposing the channel layers 540A of the channel structures 540 may be formed.

Referring to FIG. 5E, a contact plug 570 may be formed in the second opening OP2 to connect to the contact pad 520. The contact plug 570 may be electrically connected to the peripheral circuit PC through the contact pad 520. The contact plug 570 may be formed to be tilted between the second interlayer insulating layer IL2 and the insulating plug 550, and may be formed in the direction parallel to the central axis 550A of the insulating plug 550 between the stack 530S and the insulating plug 550. The contact plug 570 may include a conductive material such as, for example, tungsten.

First contact vias 580 may be formed in the via holes VH, respectively. The first contact vias 580 may be connected to the top third material layers 530C, respectively, of the step structure of the gate structure 530G. When forming the contact plug 570, the first contact vias 580 may be formed. Therefore, the first contact vias 580 may include a conductive material such as, for example, tungsten.

Second contact vias 590 may be formed in the contact holes CH, respectively. The second contact vias 590 may be connected to the channel layers 540A of the channel structures 540, respectively. When forming the contact plug 570, the second contact vias 590 may be formed. Therefore, the second contact vias 590 may include a conductive material such as, for example, tungsten.

According to the manufacturing method described above, when forming the first opening OP1, the support holes SH may be formed. When forming the insulating plug 550 in the first opening OP1, the supports 570 may be formed in the support holes SH. When forming and expanding the second opening OP2, the via holes VH may be formed. When forming the contact plug 570 in the second opening OP2, the first contact vias 580 may be formed in the via holes VH. Thus, a production cost of the semiconductor device may be reduced by unifying a process.

An extension direction of the second opening OP2 may be corrected through the insulating plug 550. For example, because the second opening OP2 may be expanded along the central axis 550A of the insulating plug 550, the second opening OP2 may be expanded in the direction parallel to the central axis 550A of the insulating plug 550. The extension direction of the tilted second opening OP2 may be aligned in the vertical direction, and the second opening OP2 may be landed at the target position.

Although embodiments according to the technical concepts of the present disclosure have been described with reference to the accompanying drawings, this is only for describing an embodiment according to the concept of the present disclosure, and the present disclosure is not limited to the above-described embodiments. Within the scope of the technical concepts of the present disclosure described in the claims, various forms of substitution, modification, and change of the embodiments will be possible by those skilled in the art to which the present disclosure belongs, and these also belong to the scope of the present disclosure. Furthermore, the embodiments may be combined to form additional embodiments.

What is claimed is:

1. A semiconductor device comprising:
a stack including insulating layers and sacrificial layers alternately stacked;
an interlayer insulating layer disposed on the stack;
an insulating plug passing through the stack and the interlayer insulating layer; and
a contact plug including a first portion and a second portion, the first portion extending between the stack and the insulating plug and having a first central axis, and the second portion extending between the interlayer insulating layer and the insulating plug and having a second central axis dislocated from the first central axis.

2. The semiconductor device of claim 1, wherein the insulating plug has a third central axis, and the contact plug passes through the insulating plug at a position biased from the third central axis.

3. The semiconductor device of claim 2, wherein the first central axis is parallel to the third central axis, and the second central axis crosses the third central axis.

4. The semiconductor device of claim 1, wherein a partial sidewall of the first portion is in contact with the insulating plug, and a remaining sidewall of the first portion is in contact with the stack.

5. The semiconductor device of claim 1, wherein a partial sidewall of the second portion is in contact with the insulating plug, and a remaining sidewall of the second portion is in contact with the interlayer insulating layer.

6. The semiconductor device of claim 1, wherein the second portion protrudes from a sidewall of the insulating plug.

7. The semiconductor device of claim 1, wherein the second portion contacts a top surface of an uppermost sacrificial layer among the sacrificial layers.

8. The semiconductor device of claim 1, further comprising:
a peripheral circuit;
a source structure disposed on or over the peripheral circuit; and
a contact pad passing through the source structure.

9. The semiconductor device of claim 8, wherein the contact plug is electrically connected to the peripheral circuit through the contact pad.

10. The semiconductor device of claim 1, further comprising:
a peripheral circuit; and
a bonding structure disposed on or over the peripheral circuit.

11. The semiconductor device of claim 10, wherein the contact plug is electrically connected to the peripheral circuit through the bonding structure.

12. The semiconductor device of claim 1, further comprising:
a gate structure disposed at a level corresponding to the stack and including insulating layers and conductive layers alternately stacked;
supports passing through the gate structure;
channel structures passing through the gate structure; and
contact vias respectively connected to the conductive layers.

13. The semiconductor device of claim 1, wherein the sacrificial layers include a material having a selectivity with respect to the interlayer insulating layer, the insulating plug, and the insulating layers.

14. The semiconductor device of claim 13, wherein the sacrificial layers include nitride, and the interlayer insulating layer, the insulating plug, and the insulating layers include oxide.

15. A semiconductor device comprising:
a peripheral circuit;
a source structure disposed on or over the peripheral circuit;
a contact pad passing through the source structure;
a stack disposed on or over the source structure and including insulating layers and sacrificial layers alternately stacked;
an interlayer insulating layer disposed on the stack;
an insulating plug passing through the stack and the interlayer insulating layer and connected to the contact pad; and
a contact plug passing through the insulating plug and connected to the contact pad, and including a first portion having a first central axis, and a second portion disposed on the first portion and having a second central axis dislocated from the first central axis.

16. The semiconductor device of claim 15, wherein the insulating plug and the first portion are connected to a top surface of the contact pad.

17. The semiconductor device of claim 15, wherein the insulating plug has a third central axis, and the contact plug passes through the insulating plug at a position biased from the third central axis.

18. The semiconductor device of claim 17, wherein the first central axis is parallel to the third central axis, and the second central axis crosses the third central axis.

19. The semiconductor device of claim 15, wherein a partial sidewall of the first portion is in contact with the insulating plug, and a remaining sidewall of the first portion is in contact with the stack.

20. The semiconductor device of claim 15, a partial sidewall of the second portion is in contact with the insulating plug, and a remaining sidewall of the second portion is in contact with the interlayer insulating layer.

21. The semiconductor device of claim 15, wherein the second portion protrudes from a sidewall of the insulating plug.

22. The semiconductor device of claim 15, wherein the second portion contacts a top surface of an uppermost sacrificial layer among the sacrificial layers.

23. The semiconductor device of claim 15, wherein the contact plug is electrically connected to the peripheral circuit through the contact pad.

24. The semiconductor device of claim 15, further comprising:
a gate structure disposed at a level corresponding to the stack and including insulating layers and conductive layers alternately stacked;
supports passing through the gate structure;
channel structures passing through the gate structure; and
contact vias respectively connected to the conductive layers.

25. A method of manufacturing a semiconductor device, the method comprising:
forming a stack including first material layers and second material layers alternately stacked;
forming a first opening passing through the stack;
forming an insulating plug in the first opening;
forming a second opening passing through the insulating plug and exposing an uppermost second material layer among the second material layers;
expanding the second opening along the insulating plug; and
forming a contact plug in the second opening.

26. The method of claim 25, wherein forming the second opening comprises etching the insulating plug using the uppermost second material layer as an etch stop layer.

27. The method of claim 25, wherein expanding the second opening comprises etching the insulating plug using the uppermost second material layer as an etch barrier.

28. The method of claim 25, wherein forming the second opening comprises etching the insulating plug in a direction dislocated from a central axis of the insulating plug.

29. The method of claim 25, wherein expanding the second opening comprises etching the insulating plug along a central axis of the insulating plug.

30. The method of claim 25, further comprising:
forming support holes passing through the stack; and
forming supports in the support holes, respectively.

31. The method of claim 30, wherein the support holes are formed when forming the first opening.

32. The method of claim 30, wherein the supports are formed when forming the insulating plug.

33. The method of claim 25, further comprising:
forming a gate structure by replacing the second material layers with third material layers;
forming via holes respectively exposing the third material layers; and
forming contact vias in the via holes, respectively.

34. The method of claim 33, wherein the via holes are formed when forming and expanding the second opening.

35. The method of claim 33, wherein the contact vias are formed when forming the contact plug.
